(19) United States
(12) Patent Application Publication
(10) Pub. No.: US 2004/0014321 A1
(43) Pub. Date: Jan. 22, 2004

(54) Methods for manufacturing contact plugs for semiconductor devices

(76) Inventors: Pan Ki Kwon, Gyeonggi-do (KR); Sang Ick Lee, Gyeonggi-do (KR)

Correspondence Address: MARSHALL, GERSTEIN & BORUN LLP, 6300 SEARS TOWER, 233 S. WACKER DRIVE, CHICAGO, IL, 60606, US

(21) Appl. No.: 10/609,505

(22) Filed: Jun. 30, 2003

(30) Foreign Application Priority Data
Jul. 19, 2002 (KR) 2002-42683

(51) Int. Cl. H01L 21/302; H01L 21/461

(52) U.S. Cl. 438/692

(57) ABSTRACT

A method for manufacturing a contact plug of a semiconductor device is disclosed. A CMP process is performed on an interlayer insulating film and a polysilicon layer using a disclosed acidic CMP slurry containing an oxidizer, thereby minimizing dishing phenomenon of the interlayer insulating film and the polysilicon layer. Accordingly, the degradation of characteristics of a device can be prevented, which results in improvement of characteristics and reliability of a semiconductor device to manufacture a highly integrated semiconductor device.

### BACKGROUND

1. Technical Field

Methods for manufacturing contact plugs of a semiconductor device are disclosed. More specifically, the disclosed methods form a stable landing plug poly (LPP) by performing a chemical mechanical polishing (CMP) process of an interlayer insulating film and a polysilicon layer, which is a plug material, by using an acidic slurry containing an oxidizer to minimize any “dishing phenomenon” associated with oxide films and polysilicon layers.

2. Description of the Related Art

In order to provide a small, high capacity, and highly integrated semiconductor device, after formation of transistor, a bit-line and a capacitor of a semiconductor device, formation process of contact plug must be performed, which can be electrically connected to each device, i.e. the transistor, bit-line and capacitor.

In general, when the formation process of a contact plug is performed, a planarization process must be performed by polishing multiple layers simultaneously by using single slurry to form a contact plug having a high aspect ratio.

However, when the multi-layered films are polished only using the single slurry, each layer is polished at a difference polishing speed because each layer has a different polishing selectivity ratio. As a result, step differences are generated among the layers and, consequently, it is difficult to apply subsequent refinement processes.

Particularly, step differences are more intensely generated at interlayer insulating films that polished at higher polishing speeds than other layers. Also, by-products of each layer generated in the polishing process and abrasive residuals of the slurry fill an upper portion of the interlayer insulating film. As a result, defects such as bridges between plugs of a device are generated.

Figs. 1a through 1d illustrate conventional methods for manufacturing contact plugs of semiconductor devices schematically.

Referring to FIG. 1a, a trench-type device isolating film 12 defining an active region is formed on a silicon substrate 11. And, a wordline conductive layer (not shown) and a hard mask film (not shown), i.e., nitride film, are formed on a cell region of the substrate 11, and sequentially etched. As a result, a wordline pattern 16 where a hard mask pattern 14 is formed on a wordline conductive layer pattern 13 is formed.

Referring to FIG. 1b, a spacer 15 is formed on a side of the wordline pattern 16. An interlayer insulating film 17 is formed on the entire surface of the resultant structure.

Referring to FIG. 1c, the interlayer insulating film 17 is selectively etched using a landing plug contact mask (not shown) to form a contact hole (not shown) for a plug.

After a polysilicon layer (not shown) is deposited on the entire surface of the resultant structure including the contact hole (not shown) for a plug, a polishing process is performed using the interlayer insulating film 17 as an etching barrier film to deposit a polysilicon layer 18 at the contact hole for a plug.

Referring to FIG. 1d, a CMP process is performed by using a general basic CMP slurry for oxide film on the entire surface of the polysilicon layer 18 and the interlayer insulating film 17 until the hard mask pattern 14 is exposed to form a plug poly 19.

The basic slurry used in the above CMP process is a conventional CMP slurry for oxide films having a pH ranging from 8 to 12 and which includes an abrasive such as colloidal or fumed SiO₂, or Al₂O₃.

Generally, slurries having these similar polishing speeds between multiple layers must be used to remove multi-layered films. However, since a conventional polishing process is performed using a basic slurry for an oxide film, the polishing selectivity ratio of the interlayer insulating film and the polysilicon layer is higher than that of the hard mask film, and the polishing selectivity ratio of the interlayer insulating film is higher than that of the polysilicon layer. As a result, the interlayer insulating film has the highest polishing speed.

When the CMP process is performed to form a landing plug poly until the hard mask insulating film formed of a nitride film is exposed, severe “dishings(21a, 21b)” are generated on the interlayer insulating film and the polysilicon layer as shown in FIG. 2a. A dishing 20b on the interlayer insulating film having the higher polishing selectivity ratio is more severely generated than a dishing 20a on the polysilicon layer.

The dishing of the interlayer insulating film requires an additional deposition process of other oxide films to prevent topology of the film from being transformed in a subsequent process. The polishing residuals resulting from the CMP process fill an upper portion of the interlayer insulating film as a result of the dishings 21a and 21b. Thus, as shown in FIG. 2b defects 22 of the landing plug poly are generated because the residuals are not removed in a subsequent cleaning process. These defects form bridges between contact plugs in a subsequent contact process, thereby degrading yield, characteristics and reliability of a device. Thus, it is difficult to embody high integration of the device.

### SUMMARY OF THE DISCLOSURE

Methods for manufacturing contact plugs of semiconductor devices disclosed where the dishing phenomenon associated with polishing of multiple layer films is minimized by using a CMP slurry for oxide film having similar selectivity to each layer.

### BRIEF DESCRIPTION OF THE DRAWINGS

FIGS. 1a through 1d schematically illustrate conventional methods for manufacturing contact plugs of semiconductor devices.

FIGS. 2a and 2b are SEM photographs showing plan and cross-sectional views of the conventional contact plug of FIG. 1d.

FIGS. 3a through 3d schematically illustrate disclosed methods for manufacturing contact plugs of semiconductor devices in accordance with this disclosure.

FIGS. 4a and 4b are SEM photographs illustrating top-view and cross-sectional of the contact plug of FIG. 3c.

FIGS. 5a and 5b are SEM photographs showing plan and cross-sectional views of the contact plug of FIG. 3d.

FIG. 6 is a graph illustrating a polishing speed when a thin film is polished on a wafer using the disclosed CMP slurry.

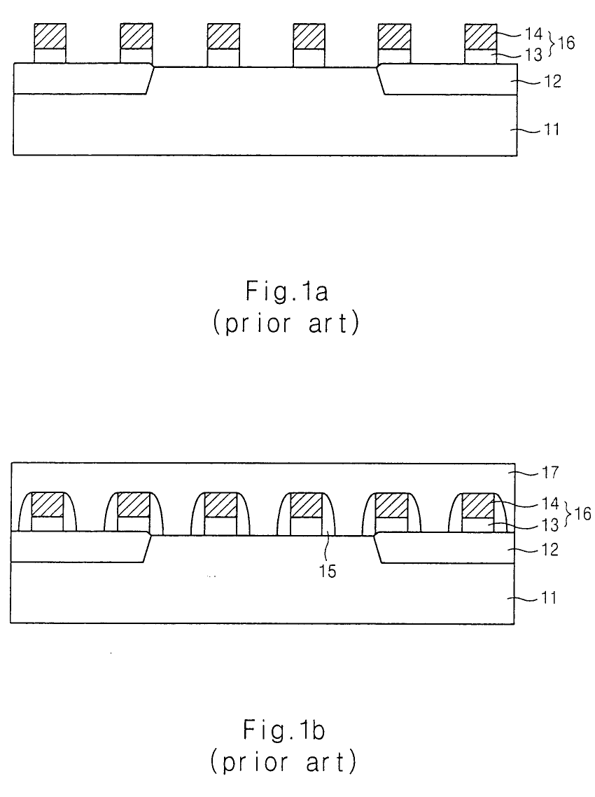

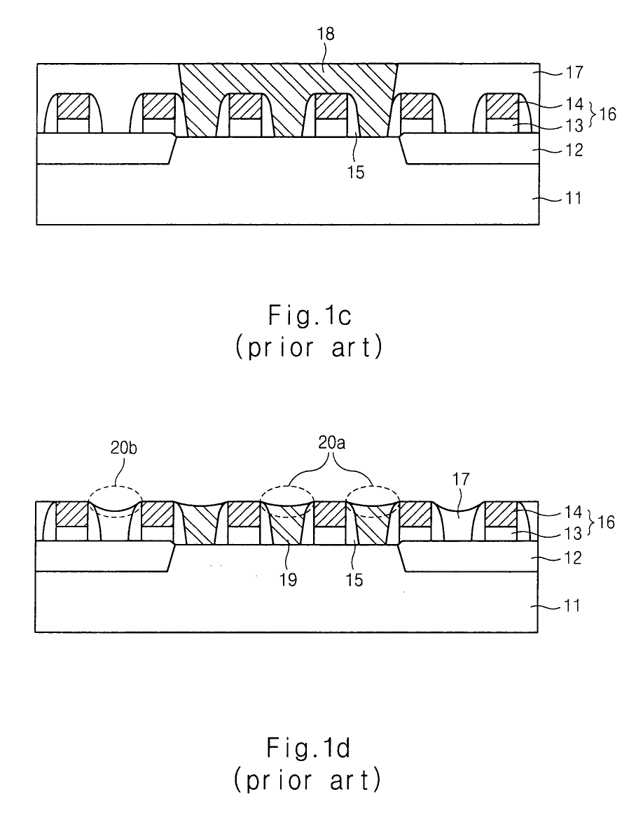

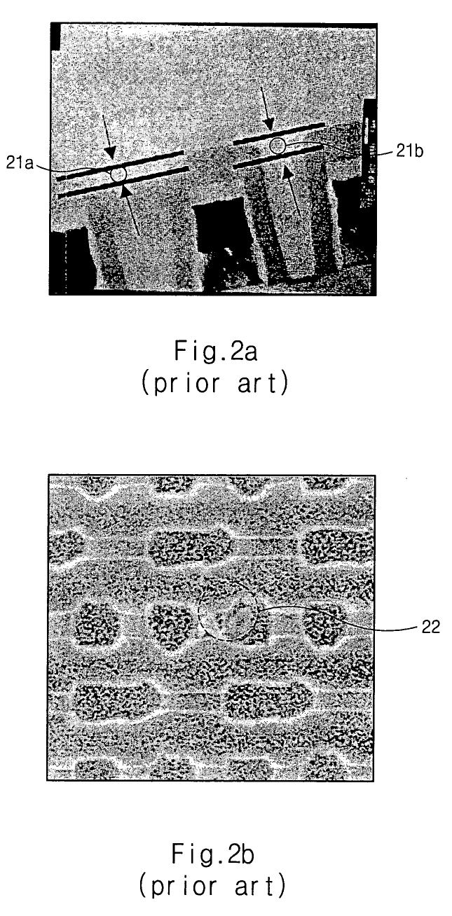

### DETAILED DESCRIPTION OF THE PRESENTLY PREFERRED EMBODIMENTS

A method for manufacturing a contact plug of a semiconductor device is disclosed. The disclosed method for manufacturing a contact plug of a semiconductor device comprises:

forming a wordline pattern having a sequentially stacked structure of a wordline conductive material and a hard mask nitride film on a semiconductor substrate;

forming a nitride film spacer on a side of the wordline pattern;

forming a planarized interlayer insulating film on the wordline pattern;

etching the interlayer insulating film until the substrate is exposed, to form a contact hole;

forming a polysilicon layer on the surface of the interlayer insulating film where the contact hole is formed; and

performing a chemical mechanical polishing (CMP) process on the polysilicon layer and the interlayer insulating film using an acidic CMP slurry for oxide film having a pH ranging from 2 to 7 containing an oxidizer until the hard mask nitride film is exposed.

The oxidizer includes hydrogen peroxide (H₂O₂), periodic acid (H₂IO₆), ferric nitrate [Fe(N₃O₉)], or combinations thereof. H₂O₂ is Preferably used for the oxidizer. The oxidizer is present in an amount ranging from 1 to 40 vol %, more preferably from 20 to 30 vol %, based on the CMP slurry.

The acidic slurry includes a pH ranging from 2 to 5 and comprises an abrasive selected from the group consisting of silica (SiO₂), ceria (CeO₂), zirconia (ZrO₂), alumina (Al₂O₃), and combinations thereof. The abrasive is present in an amount ranging from 10 to 50 wt %, more preferably from 25 to 35 wt %, based on the CMP slurry.

Generally, an alkali slurry having a pH ranging from 10 to 13 is conventionally used for a slurry for oxide film. Since the alkali slurry includes a plurality of OH— groups, a dishing phenomenon is generated on oxide films due to their chemical decomposition during a CMP process.

However, the disclosed acidic slurry for oxide films may prevent chemical decomposition of oxide films because it includes more H+ groups than OH— groups.

Since the disclosed acidic slurry for oxide films has a lower polishing selectivity ratio to polysilicon layers than that of the oxide film, the disclosed acidic slurry comprises an oxidizer to improve a polishing selectivity ratio to polycrystalline substances.

It is preferable that the polysilicon layer is formed using one selected from the group consisting of P-doped amorphous silicon film, P-doped polysilicon film, P-doped epitaxial silicon film, and combinations thereof.

The disclosed manufacturing method will be described in detail with reference to the attached drawings.

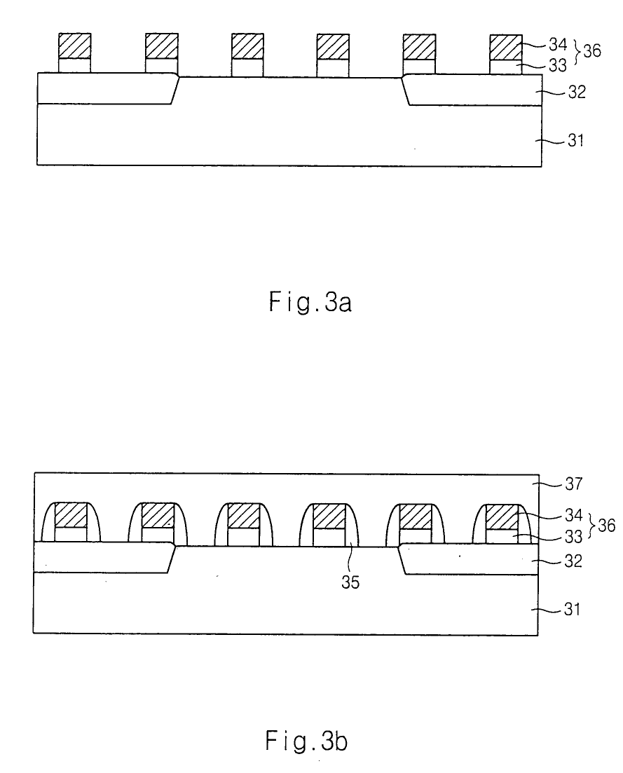

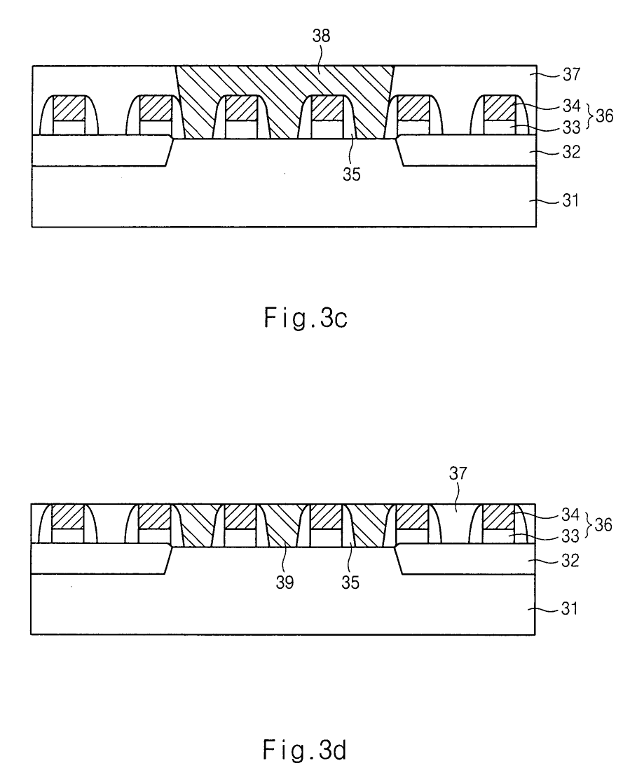

FIGS. 3a through 3d schematically illustrate disclosed methods for manufacturing contact plugs of semiconductor devices in accordance with this disclosure.

Referring to FIG. 3a, a trench-type device isolating film 32 defining an active region is formed on a silicon substrate 31. And, a wordline conductive layer (not shown) and a hard mask film (not shown), i.e., nitride film, are formed on a cell region of the substrate 31, and sequentially etched. As a result, a wordline pattern 36 where a hard mask pattern 34 is formed on a wordline conductive layer pattern 33 is formed.

It is preferable that the hard mask film composes of nitride film, and the wordline conductive layer composes a SiON or organic bottom ARC layer.

Referring to FIG. 3b, a spacer 35 is formed on a side of the wordline pattern 36. A planarized interlayer insulating film 37 is formed on the entire surface of the resultant structure.

It is preferable that the insulating film spacer is formed using a nitride film, and the interlayer insulating film is composed of insulating materials having excellent fluidity such as a BPSG (borophosphosilicate glass) or a HDP (high density plasma) oxide film.

Referring to FIG. 3c, the interlayer insulating film 37 is selectively etched using a landing plug contact mask (not shown) to form a contact hole (not shown) for a plug.

After a polysilicon layer (not shown) is deposited on the entire surface of the resultant structure including the contact hole (not shown) for a plug, a polishing process is performed using the interlayer insulating film 37 as an etching barrier film to deposit a polysilicon layer 38 at the contact hole (not shown) for a plug.

It is preferable that the polysilicon layer comprises a P-doped amorphous silicon film, P-doped polysilicon film, P-doped epitaxial silicon film, or combinations thereof

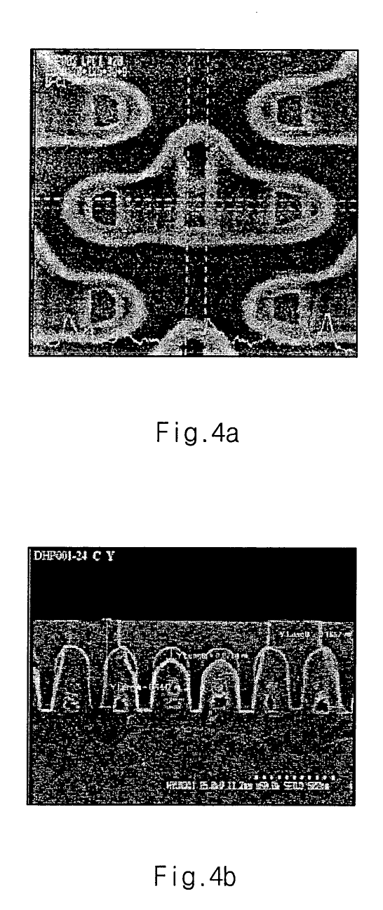

Here, the contact hole for a plug is preferably formed using a “T”-type landing plug poly (see FIG. 4a). And, in SEM photograph of FIG. 3c, it is shown that the poly for plug is formed on the contact region (see FIG. 4b).

Referring to FIG. 3d, a CMP process is performed by using the disclosed CMP slurry for oxide film on the entire surface of the polysilicon layer 38 and the interlayer insulating film 37 until the hard mask pattern 34 is exposed. As a result, a plug poly 39 is formed.

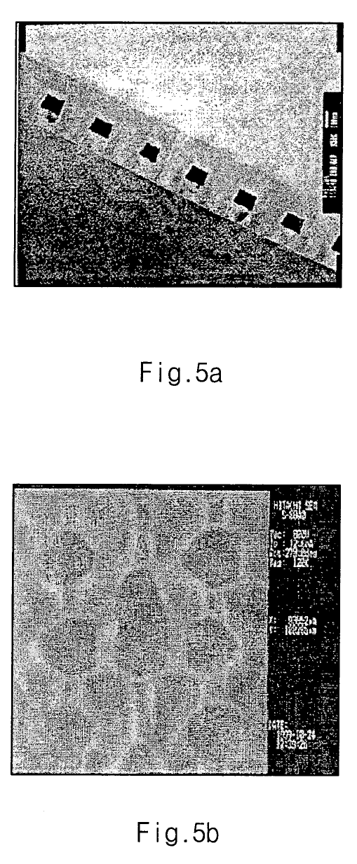

It is understood that a contact plug having few damaged portions may be formed because dishings are scarcely generated on the cross-section of the plug poly formed according to the disclosed manufacturing method (see FIGS. 5a and 5b).

The disclosed acidic CMP slurry for oxide film will be described in more detail by referring to examples below, which are not intended to be limiting.

A. Preparation of the Disclosed Slurry

### Preparation Example 1.

To a 94 wt % acidic CMP slurry for oxide film containing 30 wt % SiO2 as an abrasive was added 6 wt % H202 with stirring. Then, the resulting mixture was further stirred for about 30 minutes until the mixture was completely mixed and stabilized. As a result, disclosed slurry was prepared.

B. Comparison of Polishing Speed in Layers using the Disclosed Slurry

### Comparative Example 1.

A silicon layer was deposited on the entire surface of an interlayer insulating film including a contact hole for a plug. Then, a CMP process was performed on the silicon layer and the interlayer insulating film using conventional basic CMP slurry having no oxidizer until a hard mask nitride film is exposed.

The CMP process was performed by CMP equipment of an orbital system under a head pressure of 3 psi and a table revolution of 600 rpm.

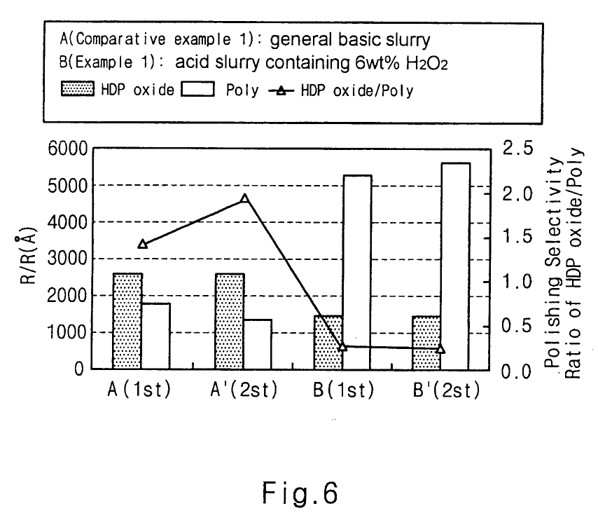

Here, the thickness of the polished oxide film and the polished polysilicon layer was individually 2609 Å and 1821 Å in the first experiment, and 2620 Å and 1342 Å in the second experiment. The oxide film/polysilicon layer was shown to have a polishing selectivity ratio of 1.43 in the first experiment and of 1.95 in the second experiment, on the average of 1.69. As a result, it was understood that the oxide film was more rapidly polished than the polysilicon layer(see FIG. 6).

### EXAMPLE 1

A silicon layer was deposited on the entire surface of an interlayer insulating film including a contact hole for a plug. Then, a CMP process was performed on the silicon layer and the interlayer insulating film using the disclosed CMP slurry obtained from Preparation Example 1 until a hard mask nitride film is exposed.

The condition of the CMP process was the same as that of Comparative

### EXAMPLE 1

As a result, the thickness of the polished oxide film and the polysilicon layer was individually 1437 Å and 5292 Å in the first experiment, and 1429 Å and 5684 Å in the second experiment. The oxide film/polysilicon layer was shown to have a polishing selectivity ratio of 0.25 in the first experiment and of 0.27 in the second experiment, on the average of 0.26. As a result, it was understood that the polysilicon layer was more rapidly polished than the oxide film (see FIG. 6).

As shown in the experiment results, when a CMP process is performed on an oxide film and a polysilicon layer using disclosed acidic CMP slurry containing an oxidizer, the polysilicon layer has the more rapid polishing speed by two times or more than the oxide film. As a result, the polysilicon layer may be easily polished.

As discussed earlier, a contact plug where the dishing phenomenon is minimized on an interlayer insulating film and a polysilicon layer can be formed via a CMP process using a disclosed acidic CMP slurry containing an oxidizer because the interlayer insulating film and the polysilicon layer have a reverse polishing selectivity ratio in a process for forming a plug poly comparing with CMP process using the conventional basic CMP slurry having no oxidizer. Accordingly, the degradation of characteristics of a device can be prevented, which results in improvement of characteristics and reliability of a semiconductor device to manufacture highly integrated semiconductor device.

What is claimed is:

1. A method for manufacturing a contact plug of a semiconductor device, the method comprising:
forming a wordline pattern having a sequentially stacked structure of a wordline conductive material and a hard mask nitride film on a semiconductor substrate;
forming a nitride film spacer on a side of the wordline pattern;
forming a planarized interlayer insulating film on the wordline pattern;
etching the interlayer insulating film until the substrate is exposed, to form a contact hole;
forming a polysilicon layer on the surface of the interlayer insulating film where the contact hole is formed; and
performing a chemical mechanical polishing (CMP) process on the polysilicon layer and the interlayer insulating film using an acidic CMP slurry for oxide film having a pH ranging from 2 to 7 containing an oxidizer until the hard mask nitride film is exposed.

2. The method according to claim 1, wherein the oxidizer is selected from the group consisting of hydrogen peroxide (H₂O₂), periodic acid (H₂IO₆), ferric nitrate [Fe(N₃O₉)], and combinations thereof.

3. The method according to claim 1, wherein the oxidizer is present in an amount ranging from 1 to 40 vol % based on the CMP slurry.

4. The method according to claim 1, wherein the oxidizer is present in an amount ranging from 20 to 30 vol % based on the CMP slurry.

5. The method according to claim 1, wherein the acidic slurry has a pH ranging from 2 to 5.

6. The method according to claim 1, wherein the acidic slurry comprises an abrasive selected from the group consisting of silica (SiO₂), ceria (CeO₂), zirconia (ZrO₂), alumina (Al₂O₃), and combinations thereof.

7. The method according to claim 6, wherein the abrasive is present in an amount ranging from 10 to 50 wt % based on the CMP slurry.

8. The method according to claim 7, wherein the abrasive is present in an amount ranging from 25 to 35 wt % based on the CMP slurry.

9. The method according to claim 1, wherein the polysilicon layer is formed using one selected from the group consisting of P-doped amorphous silicon film, P-doped polysilicon film, P-doped epitaxial silicon film, and combinations thereof.

10. The method according to claim 1, wherein the wordline conductive material is formed of a SiON or organic bottom ARC layer.

11. The method according to claim 1, wherein the interlayer insulating film is formed of a BPSG (borophosphosilicate glass) or HDP (high density plasma) oxide film.

12. A method for manufacturing a contact plug of a semiconductor device, comprises:
forming a wordline pattern having a sequentially stacked of a wordline conductive material and a hard mask nitride film on a semiconductor substrate;
forming a nitride film spacer on a side of the wordline pattern;
forming a planarized interlayer insulating film on the wordline pattern;
etching the interlayer insulating film until the substrate is exposed to form a contact hole;
forming a polysilicon layer on the surface of the interlayer insulating film where the contact hole is formed; and
performing a CMP process on the polysilicon layer and the interlayer insulating film using a CMP slurry for oxide film having a pH ranging 2 to 7 containing H₂O₂ in an amount ranging from 1 to 40 vol %.

13. The method according to claim 12, wherein the oxidizer is present in an amount ranging from 20 to 30 vol % based on the CMP slurry.

14. The method according to claim 12, wherein the acidic slurry has a pH ranging from 2 to 5.

15. The method according to claim 12, wherein the acidic slurry comprises an abrasive selected from the group consisting of silica (SiO₂), ceria (CeO₂), zirconia (ZrO₂), alumina (Al₂O₃), and combinations theorof.

16. The method according to claim 15, wherein the abrasive is present in an amount ranging from 10 to 50 wt % based on the CMP slurry.

17. The method according to claim 15, wherein the abrasive is present in an amount ranging from 25 to 35 wt % based on the CMP slurry.

18. The method according to claim 12, wherein the polysilicon layer is formed using one selected from the group consisting of P-doped amorphous silicon film, P-doped polysilicon film, P-doped epitaxial silicon film, and combinations thereof.

19. The method according to claim 12, wherein the wordline conductive material is formed of a SiON or organic bottom ARC layer.

20. The method according to claim 12, wherein the interlayer insulating film is formed of a BPSG (borophosphosilicate glass) or HDP (high density plasma) oxide film.
